(19) United States
(12) Patent Application Publication
(10) Pub. No.: US 2013/0146931 A1
(43) Pub. Date: Jun. 13, 2013

(54) PIXEL STRUCTURE AND MANUFACTURING METHOD OF THE SAME

(71) Applicants: Kuang-hua LIU, New Taipei City (TW); Huai-an LI, Zhongli City (TW)

(72) Inventors: Kuang-hua LIU, New Taipei City (TW); Huai-an LI, Zhongli City (TW)

(73) Assignee: CHUNGHWA PICTURE TUBES, LTD., Bade City (TW)

(21) Appl. No.: 13/411,566

(22) Filed: Mar. 4, 2012

(30) Foreign Application Priority Data
Dec. 7, 2011 (TW) 100145157

(51) Int. Cl. H01L 33/36

(52) U.S. Cl. 257/99; 438/22; 257/E33.062

(57) ABSTRACT

A pixel structure and manufacturing method of the same are described. The pixel structure includes a substrate, a switch transistor, a dielectric layer, a conducting connection line, a driving transistor, a capacitor and a pixel electrode. The substrate defines a transistor region and the switch transistor is disposed on the transistor region. The dielectric layer is disposed on the substrate and covers the switch transistor. The conducting connection line disposed on the dielectric layer is located over the transistor region. The driving transistor disposed on the dielectric layer is vertically stacked over the switch transistor and transistor region. The conducting connection line electrically connects the switch transistor to the driving transistor. The pixel electrode is electrically connected to the driving transistor.

### FIELD OF THE INVENTION

The present invention relates to a pixel structure and thereof, and more particularly to a pixel structure and manufacturing method thereof having stacked transistors.

### BACKGROUND OF THE INVENTION

The organic light-emitted diode (OLED) display device utilizes driving current to drive the organic light-emitted diode. Since the organic thin-film of OLED display device is self-illumination film, therefore, there is no need a backlight module for the display device to save the power consumption and simplify the manufacturing process of the display panel, which has an attracted much attention in the display technology.

FIG. 1 is a schematic circuit layout view of a conventional pixel structure 1. The pixel structure 1 includes a switch transistor 2, a driving transistor 4, a capacitor 6 and a LED 8. When the scan signal activates the scan line 12, the data signal of the data line 16 is stored in the capacitor 6 in form of voltage manner by way of the switch transistor 2 for turning on the driving transistor 4. The driving transistor 4 is connected to the first voltage level Vdd and the OLED 8, and the driving transistor 4 is driven by the capacitor 6 for providing the OLED 8 with the driving current. The OLED 8 is connected to the second voltage level Gnd (not shown) so that the OLED 8 receives the driving current and thus generates light energy to form the self-illumination. As shown in FIG. 1, in the pixel structure 1, the switch transistor 2 and driving transistor 4 are allocated in parallel arrangement. That is, the switch transistor 2 and driving transistor 4 are located in two sides of the pixel structure. The switch transistor 2 is connected to the driving transistor 4 by a transmission region 3. The OLED 8 is disposed in the pixel electrode 5 and coupled to the driving transistor 4.

As shown in FIG. 1, the aperture rate is defined as an effective area ratio of the pixel electrode 5 area to the pixel unit 7 area where the light can pass through the liquid crystal in the pixel electrode 5. When the aperture rate is increased, the transmittance and the brightness are higher to be a better display quality. However, the driving transistor 4 occupies a portion of the pixel unit 7 area. In other words, the witch transistor 2 and driving transistor 4 occupy the area of the pixel unit 7 to shrink the pixel electrode 5 so that lighting interface of the OLED is blocked. Further, the transmission region 3 also occupies another portion of the area of the pixel unit 7 to considerably scale down the area of the pixel electrode 5. If more than two transistors are used, the area of the pixel electrode 5 and aperture rate are severely reduced so that the transmittance and display quality of the display device are disadvantageously. Moreover, the capacitor 6 composed of a portion of transmission region 3 and common line 9 consumes a portion of the pixel unit 7. Consequently, there is a need to develop a novel pixel structure to solve the aforementioned problems of lower aperture rate and transmittance.

### SUMMARY OF THE INVENTION

The first objective of the present invention is to provide a pixel structure and manufacturing method thereof for saving the occupied area of the transistors to increase the transmittance of the pixel structure.

According to the above objective, the present invention sets forth the pixel structure and manufacturing method thereof. In a first embodiment, the manufacturing method includes the steps of:
(a) forming a switch transistor on a substrate which defines a transistor region and a pixel region, wherein the switch transistor is disposed in the transistor region and the switch transistor comprises a first gate electrode, a first gate insulating layer, a first channel structure, a first source electrode and a first drain electrode;
(b) forming a first dielectric layer on the substrate to cover the switch transistor;
(c) forming a conducting connection line on the first dielectric layer, wherein the conducting connection line is disposed over the transistor region and comprises a first contact pad, a second gate electrode electrically connected to the first contact pad, and a second contact pad electrically connected to the second gate electrode;
(d) forming a driving transistor on the first dielectric layer for vertically stacking the driving transistor over the switching transistor and the transistor region, wherein the driving transistor comprises a second gate electrode, a second gate insulating layer, a second channel structure, a second source electrode and a second drain electrode corresponding to the first gate electrode, the first gate insulating layer, the first channel structure, the first source electrode and the first drain electrode respectively for connecting the first drain electrode to the second gate electrode by way of the first contact pad;
(e) forming a common line on the second gate insulating layer for connecting the common line to the second source electrode, wherein the common line is partially overlapped with the second contact pad to form a capacitor; and
(f) forming a pixel electrode for electrically connecting to the second drain electrode.

In a second embodiment of the present invention, a pixel structure includes:
a substrate, for defining a transistor region;
a switch transistor disposed on the transistor region of the substrate, wherein the switch transistor comprises a first gate electrode, a first gate insulating layer, a first channel structure, a first source electrode and a first drain electrode;
a first dielectric layer disposed on the substrate to cover the switch transistor;
a conducting connection line disposed on the first dielectric layer and over the transistor region, wherein the conducting connection line comprises a first contact pad, a second gate electrode electrically connected to the first contact pad, and a second contact pad electrically connected to the second gate electrode;
a driving transistor disposed on the first dielectric layer for vertically stacking the driving transistor over the switching transistor and the transistor region, wherein the driving transistor comprises a second gate electrode, a second gate insulating layer, a second channel structure, a second source electrode and a second drain electrode corresponding to the first gate electrode, the first gate insulating layer, the first channel structure, the first source electrode and the first drain electrode respectively for electrically connecting the first drain electrode to the second gate electrode by way of the first contact pad;
a capacitor; and
a pixel electrode electrically connected to the second drain electrode.,

In a third embodiment of the present invention, a pixel structure includes:
a substrate, for defining a transistor region;
a switch transistor disposed on the transistor region of the substrate;
a first dielectric layer disposed on the substrate to cover the switch transistor;
a conducting connection line disposed on the first dielectric layer and over the transistor region;
a driving transistor disposed on the first dielectric layer for vertically stacking the driving transistor over the switching transistor and the transistor region, wherein the switch transistor connects the driving transistor by way of the conducting connection line;
a capacitor; and
a pixel electrode electrically connected to the driving transistor.

According to the above-mentioned descriptions, the pixel structure and manufacturing method thereof of the present invention save the occupied area of the transistors to increase the transmittance of the pixel structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic circuit layout view of a conventional pixel structure;

FIG. 2A is a schematic equivalent circuit of a pixel structure of an organic light-emitted diode (OLED) for a display apparatus according to one embodiment of the present invention;

FIG. 2B is a schematic top view of the circuit layout of a switch transistor in the pixel structure according to one embodiment of the present invention;

FIG. 2C is a schematic cross-sectional view of manufacturing process of the array substrate along line A-A′ shown in FIG. 2B according to one embodiment of the present invention;

FIG. 3A is a schematic top view of a first dielectric layer of pixel structure according to one embodiment of the present invention;

FIG. 3B is a schematic cross-sectional view of manufacturing process of the array substrate along line B-B′ shown in FIG. 3A according to one embodiment of the present invention;

FIG. 4A is a schematic top view of a conducting connection line of pixel structure according to one embodiment of the present invention;

FIG. 4B is a schematic cross-sectional view of manufacturing process of the array substrate along line C-C′ shown in FIG. 4A according to one embodiment of the present invention;

FIG. 5A is a schematic top view of a driving transistor and a common line of pixel structure according to one embodiment of the present invention;

FIG. 5B is a schematic cross-sectional view of manufacturing process of the array substrate along line D-D′ shown in FIG. 5A according to one embodiment of the present invention;

FIG. 6A is a schematic top view of a second dielectric layer of pixel structure according to one embodiment of the present invention;

FIG. 6B is a schematic cross-sectional view of manufacturing process of the array substrate along line E-E′ shown in FIG. 6A according to one embodiment of the present invention;

FIG. 7A is a schematic top view of a pixel electrode of pixel structure according to one embodiment of the present invention;

FIG. 7B is a schematic cross-sectional view of manufacturing process of the array substrate along line F-F′ shown in FIG. 7A according to one embodiment of the present invention; and

FIG. 8 is a schematic cross-sectional view of the pixel structure having five stacked transistors according to another embodiment of the present invention.

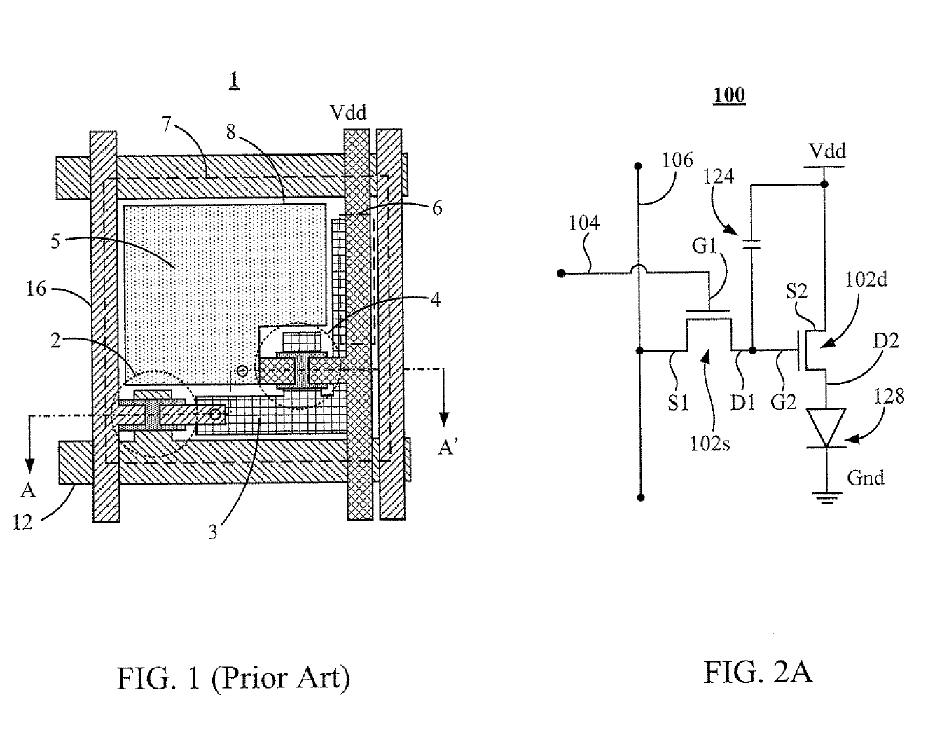

### DETAILED DESCRIPTION OF THE PREFERRED EMBODIMENTS

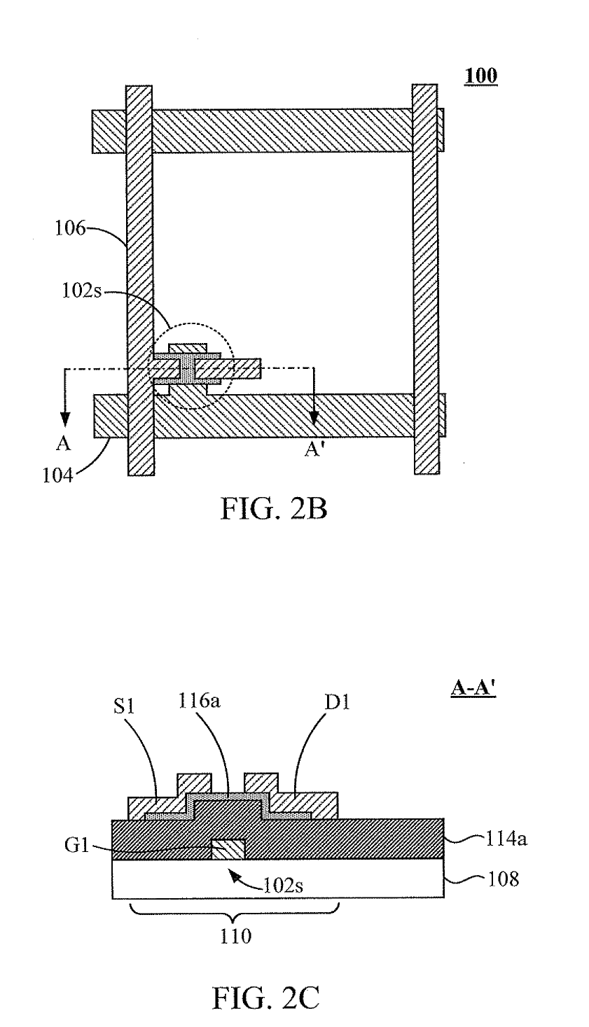

FIG. 2A is a schematic equivalent circuit of a pixel structure 100 of an organic light-emitted diode (OLED) for a display apparatus according to one embodiment of the present invention. The pixel structure 100 includes a switch transistor 102s, a driving transistor 102d, a capacitor 124, and an OLED 128. The driving transistor 102d is stacked on the switch transistor 102s for saving the occupied area of the driving transistor 102d and the conducting connection line on the substrate 108 to increase the aperture rate of the pixel structure 100 and enhance the display quality of liquid crystal display (LCD) panel. The manufacturing process of the pixel structure 100 and structure thereof are described as follows.

Please refer to FIG. 2B and FIG. 2C. FIG. 2B is a schematic top view of the circuit layout of a switch transistor 102s in the pixel structure 100 according to one embodiment of the present invention. FIG. 2C is a schematic cross-sectional view of manufacturing process of the array substrate along line A-A′ shown in FIG. 2B according to one embodiment of the present invention.

The pixel structure 100 is applicable to the OLED array of LCD panel and the LCD panel further includes a plurality of scan lines 104, a plurality of data lines 106 and a plurality of pixel structures 100. Each of the pixel structures 100 is disposed in the insulated intersection between each scan line 104 and each data line 106. For simplification of the present invention, a pixel structure 100 is taken as an example herein, but not limited.

As shown in FIG. 2B and FIG. 2C, the switch transistor 102s is formed on the substrate 108 which defines a transistor region 110. The area of transistor 110 is approximately equal to the area of switch transistor 102s on the substrate 108. The switch transistor 102s is disposed on the transistor region 110 of the substrate 108 wherein the switch transistor 102s includes a first gate electrode G1, a first gate insulating layer 114a, a first channel structure 116a, a first source electrode S1 and a first drain electrode D1.

In one embodiment, while forming the switch transistor 102s, the first gate electrode G1 connected to the scan line 104 is formed on the substrate 108 firstly. The first gate insulating layer 114a is then formed on the first gate electrode 01 and the substrate 108. The first channel structure 116a is formed on the first gate insulating layer 114a. The first source electrode S1 and the first drain electrode D1 are then formed on the first channel structure 116a to form the switch transistor 102s wherein the first source electrode S1 connects to the data line 106.

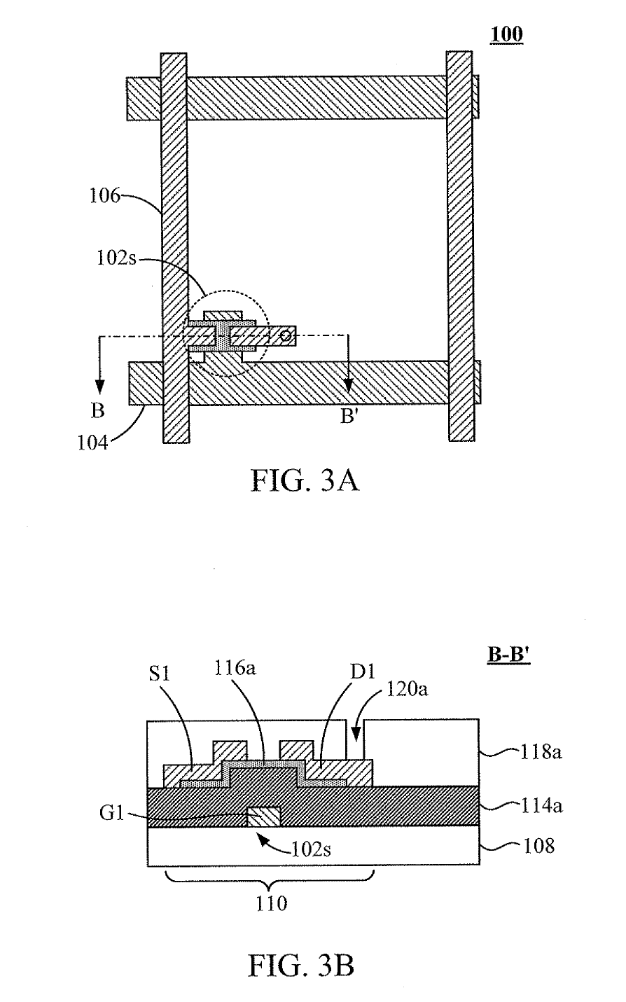

Please refer to FIG. 3A and FIG. 3B. FIG. 3A is a schematic top view of a first dielectric layer 118a of pixel structure 100 according to one embodiment of the present invention. FIG. 3B is a schematic cross-sectional view of manufacturing process of the array substrate along line B-B′ shown in FIG. 3A according to one embodiment of the present invention. As shown in FIG. 3A and FIG. 3B, a first dielectric layer 118a is formed on the substrate 108 to cover the switch transistor 102s.

In one embodiment, the first dielectric layer 118a is etched to form a first dielectric via 120a and partially expose the first drain electrode D1 so that the first drain electrode D1 is connected to the second gate electrode G2 and the capacitor 124 by way of the first dielectric via 120a. For example, a lithography etching is used to form the first dielectric via 120a.

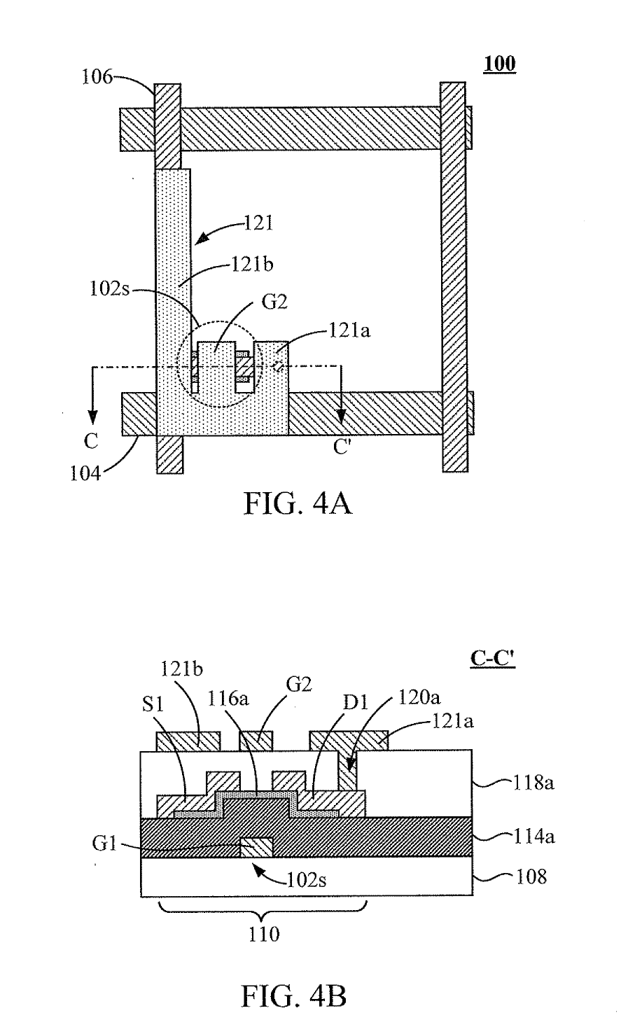

Please refer to FIG. 4A and FIG. 4B. FIG. 4A is a schematic top view of a conducting connection line 121 of pixel structure 100 according to one embodiment of the present invention. FIG. 4B is a schematic cross-sectional view of manufacturing process of the array substrate along line C-C′ shown in FIG. 4A according to one embodiment of the present invention. As shown in FIG. 4A and FIG. 4B,

A conducting connection line 121 is formed on the first dielectric layer 118a wherein the conducting connection line 120 is disposed over the transistor region 110 and includes a first contact pad 121a, a second gate electrode G2 electrically connected to the first contact pad 121a, and a second contact pad 121b electrically connected to the second gate electrode G2. The first contact pad 121a fills the first dielectric via 120a for electrically connecting the second gate electrode G2 to the first drain electrode D1. That is, the first contact pad 121a is electrically connected to the first drain electrode D1 by way of the first dielectric via 120a.

Specifically, the conducting connection line 121 and the second gate electrode G2 are disposed on the first dielectric layer 118a corresponding to the transistor region 110. The second contact pad 121b extends from the second gate electrode G2 to the data line 106 and overlaps with the data line 106. The first contact pad 121a on the transistor region 110 includes arbitrary geometrical shape and the area of the first contact pad 121a is effectively reduced while the requirement of the signal transmission resistance can be met. For example, the material of conducting connection line 121 is metal.

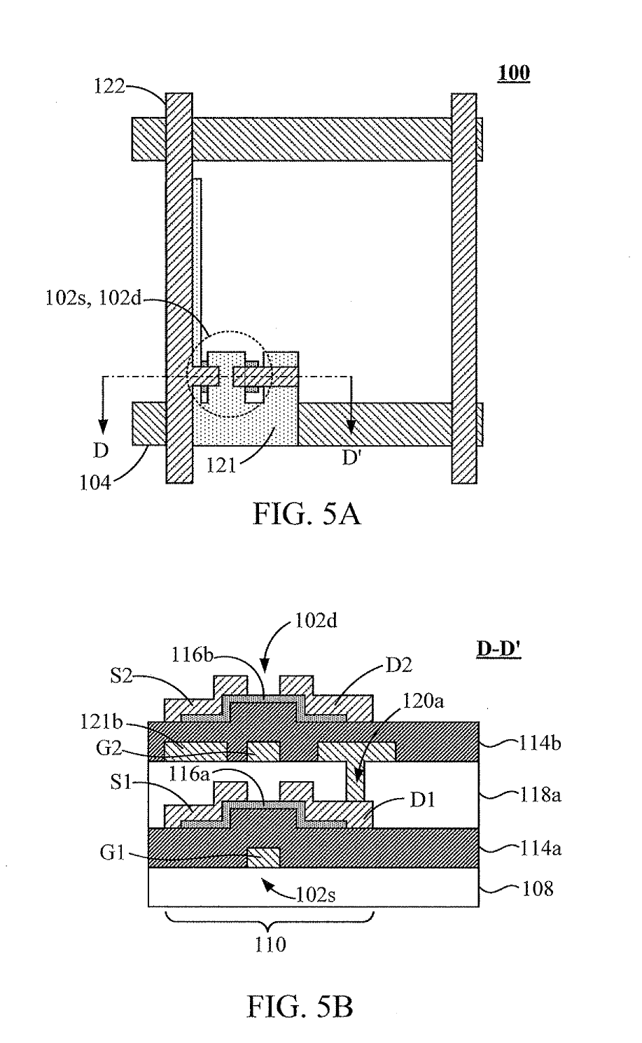

Please refer to FIG. 5A and FIG. 5B. FIG. 5A is a schematic top view of a driving transistor 102d and a common line 122 of pixel structure 100 according to one embodiment of the present invention. FIG. 5B is a schematic cross-sectional view of manufacturing process of the array substrate along line D-D′ shown in FIG. 5A according to one embodiment of the present invention. As shown in FIG. 5A and FIG. 5B. FIG. 5A, a driving transistor 102d is formed on the first dielectric layer 118a for vertically stacking the driving transistor 102d over the switching transistor 102s and the transistor region 110.

Specifically, the driving transistor 102d includes a second gate electrode G2, a second gate insulating layer 114b, a second channel structure 116b, a second source electrode S2 and a second drain electrode D2 corresponding to the first gate electrode G1, the first gate insulating layer 114a, the first channel structure 116a, the first source electrode S1 and the first drain electrode D1 respectively for connecting the first drain electrode D1 to the second gate electrode G2 by way of the first contact pad 121a. In one preferred embodiment, the first gate electrode G1, the first channel structure 116a, the first source electrode S1 and the first drain electrode D1 are aligned to the second gate electrode G2, the second channel structure 116b, the second source electrode S2 and the second drain electrode D2 respectively in the transistor region 110. That is, the driving transistor 102d is vertically aligned to the switching transistor 102s for saving the occupied area of the driving transistor 102d on the substrate 108. Thus, only the area of switching transistor 102s is used.

In one embodiment, the second gate insulating layer 114b is formed on the conducting connection line 121 and the first dielectric layer 118a. The second channel structure 116b is then formed on the second gate insulating layer 114b. The second source electrode S2 and the second drain electrode D2 are formed on the second channel structure 116b for forming the driving transistor 102d corresponding to the switch transistor 102s on the transistor region 110.

Please continuously refer to FIG. 5A and FIG. 5B. A common line 122 is formed on the second gate insulating layer 114b for connecting the common line 122 to the second source electrode S2 wherein the common line 122 is partially overlapped with the second contact pad 121b of the conducting connection line 121 to form a capacitor 124. In other words, the overlapped portion between the common line 122 and the second contact pad 121b disposed over and under the second gate insulating layer 114b respectively forms the electrodes of the capacitor 124. In one preferred embodiment, since the overlapped portion between the common line 122 and the second contact pad 121b is disposed on the data line 106, the occupied area of the capacitor 124 can be effectively reduced.

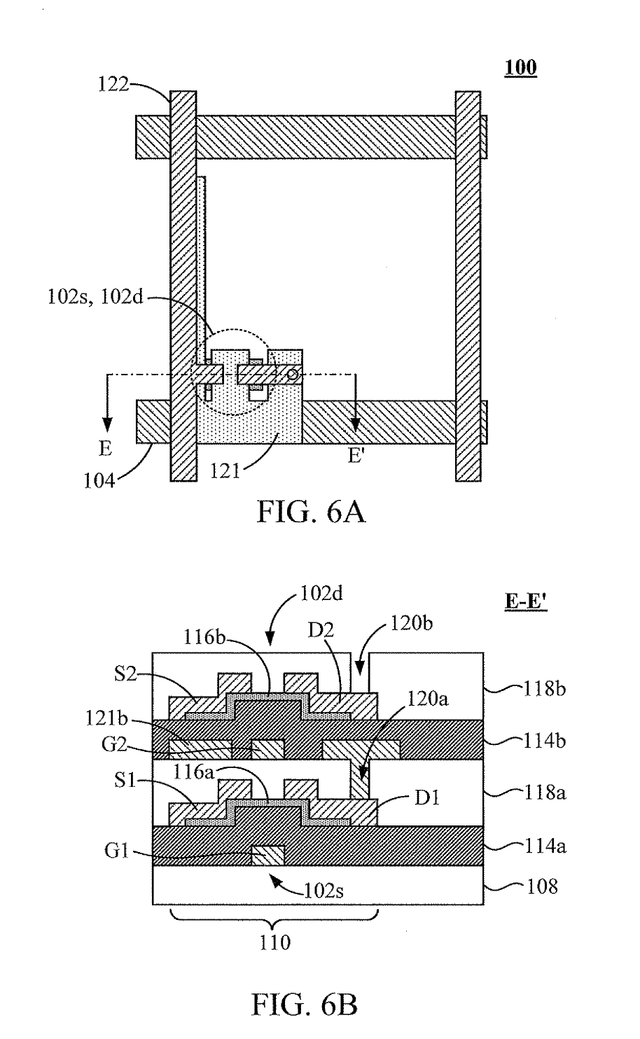

Please refer to FIG. 6A and FIG. 6B. FIG. 6A is a schematic top view of a second dielectric layer 118b of pixel structure 100 according to one embodiment of the present invention. FIG. 6B is a schematic cross-sectional view of manufacturing process of the array substrate along line E-E′ shown in FIG. 6A according to one embodiment of the present invention. As shown in FIG. 6A and FIG. 6B, a second dielectric layer 118b is formed on the second gate insulating layer 114b to cover the common line 122, the second gate insulating layer 114b and the driving transistor 102d. In one embodiment, the second dielectric layer 118b is etched to form a second dielectric via 120b and partially expose the second drain electrode D2 for electrically connecting the pixel electrode 126 to the second drain electrode D2 by way of the second dielectric via 120b. For example, a lithography etching is used to form the second dielectric via 120b.

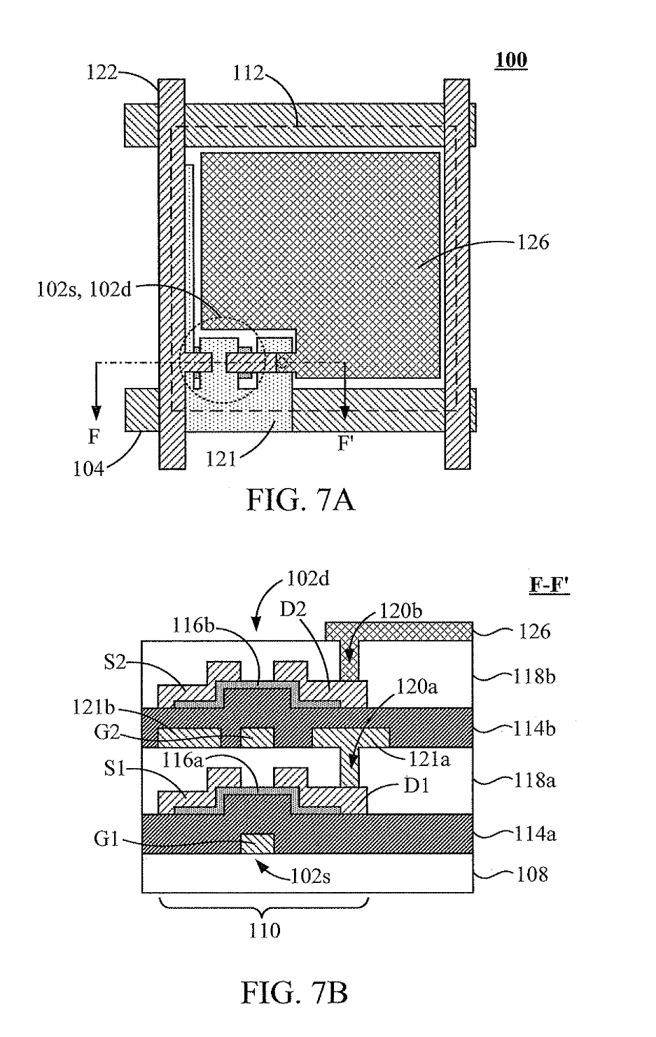

Please refer to FIG. 7A and FIG. 7B. FIG. 7A is a schematic top view of a pixel electrode 126 of pixel structure 100 according to one embodiment of the present invention. FIG. 7B is a schematic cross-sectional view of manufacturing process of the array substrate along line F-F′ shown in FIG. 7A according to one embodiment of the present invention. As shown in FIG. 7A and FIG. 7B, the pixel electrode 126 is formed on the pixel region 112 to be electrically connected to the second drain electrode D2. For example, the material of the pixel electrode 126 is transparent conducting material, e.g. indium tin oxide (ITO) and transmits the driving current to the OLED 128.

In FIG. 7A and FIG. 7B, the pixel structure 100 includes a substrate 108, a switch transistor 102s, a first dielectric layer 118a, a conducting connection line 121, a driving transistor 102d, a capacitor 124 and a pixel electrode 126. The substrate 108 defines a transistor region 110. The switch transistor 102s is disposed on the transistor region 110 of the substrate 108 wherein the switch transistor 102s includes a first gate electrode G1, a first gate insulating layer 114a, a first channel structure 116a, a first source electrode S1 and a first drain electrode D1. The first dielectric layer 118a is disposed on the substrate 108 to cover the switch transistor 102s. The conducting connection line 121 is disposed on the first dielectric layer 118a and over the transistor region 110 wherein the conducting connection line 121 includes a first contact pad 121a, a second gate electrode G2 electrically connected to the first contact pad 121a, and a second contact pad 121b electrically connected to the second gate electrode G2.

The driving transistor 102d is disposed on the first dielectric layer 118a for vertically stacking the driving transistor 102d over the switching transistor 102s and the transistor region 110. The driving transistor 102d includes a second gate electrode G2, a second gate insulating layer 114b, a second channel structure 116b, a second source electrode S2 and a second drain electrode D2 corresponding to the first gate electrode G1, the first gate insulating layer 114a, the first channel structure 116a, the first source electrode S1 and the first drain electrode D1 respectively for electrically connecting the first drain electrode D1 to the second gate electrode G2 by way of the first contact pad 121a. The pixel electrode 126 disposed in the pixel region 112 is electrically connected to the second drain electrode D2.

The aperture rate is defined as the ratio of the pixel electrode 126 area to the pixel unit 112 area. While the area of transistor region 110 is increased, the area of pixel electrode 126 is decreased. Conversely, while the area of transistor region 110 is decreased, the area of pixel electrode 126 and the aperture rate are beneficially increased. The present invention utilizes the driving transistor 102d to be stacked on the switch transistor 102s for saving the occupied area of the driving transistor 102d and the conducting connection line 121 on the substrate 108 to increase the aperture rate of the pixel structure 100 and enhance the display quality of liquid crystal display (LCD) panel.

Alternatively, in the pixel structure and manufacturing method of the present invention, the switch transistor 102s and the driving transistor 102d can be change mutually. That is, the switch transistor 102s can be stacked on the driving transistor 102d so that the switch transistor 102s and the driving transistor 102d are located in the transistor region 110 to effectively reduce the occupied area of the substrate 108.

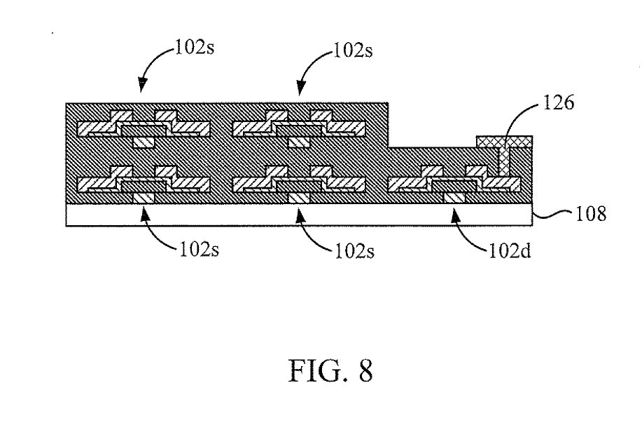

In another embodiment, while more than two transistors are stacked, two transistors are first stacked and arranged within the transistor region 110, which means that two transistors occupies the transistor region 110. FIG. 8 is a schematic cross-sectional view of the pixel structure having five stacked transistors 102s, 102d according to another embodiment of the present invention. The second switch transistor 102s2 is stacked on the first switch transistor 102s1 and the fourth switch transistor 102s4 is stacked on the third switch transistor 102s3. Further, the stacked transistors 102s1, 102s2 are adjacent to the stacked transistors 102s3, 102s4 in parallel, and the driving transistor 102d is electrically connected to the pixel electrode 126. The manufacturing method of more than two transistors is the same as the method of two transistors in the above-mentioned descriptions and it is omitted herein.

According to the above descriptions, the pixel structure and manufacturing method of the present invention saves the occupied area of the transistors to increase the transmittance and enhance the display quality of liquid crystal display (LCD) panel.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A manufacturing method of a pixel structure, the manufacturing method comprising the steps of:
(a) forming a switch transistor on a substrate which defines a transistor region and a pixel region, wherein the switch transistor is disposed in the transistor region and the switch transistor comprises a first gate electrode, a first gate insulating layer, a first channel structure, a first source electrode and a first drain electrode;
(b) forming a first dielectric layer on the substrate to cover the switch transistor;
(c) forming a conducting connection line on the first dielectric layer, wherein the conducting connection line is disposed over the transistor region and comprises a first contact pad, a second gate electrode electrically connected to the first contact pad, and a second contact pad electrically connected to the second gate electrode;
(d) forming a driving transistor on the first dielectric layer for vertically stacking the driving transistor over the switching transistor and the transistor region, wherein the driving transistor comprises a second gate electrode, a second gate insulating layer, a second channel structure, a second source electrode and a second drain electrode corresponding to the first gate electrode, the first gate insulating layer, the first channel structure, the first source electrode and the first drain electrode respectively for connecting the first drain electrode to the second gate electrode by way of the first contact pad;
(e) forming a common line on the second gate insulating layer for connecting the common line to the second source electrode, wherein the common line is partially overlapped with the, second contact pad to form a capacitor; and
(f) forming a pixel electrode for electrically connecting to the second drain electrode.

2. The manufacturing method of claim 1, wherein the step (a) further comprises the steps of:
(a1) forming the first gate electrode on the substrate, wherein the first gate electrode connects to a scan line;
(a2) forming the first gate insulating layer on the first gate electrode and the substrate;
(a3) forming the first channel structure on the first gate insulating layer; and
(a4) forming the first source electrode and the first drain electrode on the first channel structure to form the switch transistor, wherein the first source electrode connects to a data line intersected with the scan line.

3. The manufacturing method of claim 1, wherein there is a step (b1) after the step (b): etching the first dielectric layer to form a first dielectric via and partially expose the first drain electrode for electrically connecting the first contact pad to the first drain electrode by way of the first dielectric via.

4. The manufacturing method of claim 1, wherein the step (d) further comprises the steps of:
(d1) forming the second gate insulating layer on the conducting connection line and the first dielectric layer;
(d2) forming the second channel structure on the second gate insulating layer; and
(d3) forming the second source electrode and the second drain electrode on the second channel structure for forming the driving transistor corresponding to the switch transistor on the transistor region.

5. The manufacturing method of claim 1, wherein there is a step (f1) after the step (e): forming a second dielectric layer on the second gate insulating layer to cover the common line.

6. The manufacturing method of claim 5, wherein there is a step (f2) after the step (f1): etching the second dielectric layer to form a second dielectric via and partially expose the second drain electrode for electrically connecting the pixel electrode to the second drain electrode by way of the second dielectric via.

7. A pixel structure, comprising:
a substrate, for defining a transistor region;
a switch transistor disposed on the transistor region of the substrate, wherein the switch transistor comprises a first gate electrode, a first gate insulating layer, a first channel structure, a first source electrode and a first drain electrode;
a first dielectric layer disposed on the substrate to cover the switch transistor;
a conducting connection line disposed on the first dielectric layer and over the transistor region, wherein the conducting connection line comprises a first contact pad, a second gate electrode electrically connected to the first contact pad, and a second contact pad electrically connected to the second gate electrode;
a driving transistor disposed on the first dielectric layer for vertically stacking the driving transistor over the switching transistor and the transistor region, wherein the driving transistor comprises a second gate electrode, a second gate insulating layer, a second channel structure, a second source electrode and a second drain electrode corresponding to the first gate electrode, the first gate insulating layer, the first channel structure, the first source electrode and the first drain electrode respectively for electrically connecting the first drain electrode to the second gate electrode by way of the first contact pad;
a capacitor; and
a pixel electrode electrically connected to the second drain electrode.

8. The pixel structure of claim 7, further comprising a common line disposed on the second gate insulating layer for connecting the common line to the second source electrode, wherein the common line is partially overlapped with the second contact pad to form the capacitor.

9. The pixel structure of claim 8, further comprising a second dielectric layer disposed on the second gate insulating layer to cover the common line.

10. The pixel structure of claim 7, wherein the first gate electrode disposed on the substrate connects to a scan line, and the first gate insulating layer is disposed on the first gate electrode and the substrate.

11. The pixel structure of claim 7, wherein the first channel structure is disposed on the first gate insulating layer, the first source electrode and the first drain electrode are disposed on the first channel structure to form the switch transistor, and the first source electrode is connected to a data line.

12. The pixel structure of claim 7, wherein the first dielectric layer further comprises a first dielectric via and partially exposes the first drain electrode for electrically connecting the first contact pad to the first drain electrode by way of the first dielectric via.

13. The pixel structure of claim 7, wherein the second gate insulating layer is disposed on the conducting connection line and the first dielectric layer.

14. The pixel structure of claim 7, wherein the second channel structure is disposed on the second gate insulating layer, and the second source electrode and the second drain electrode are disposed on the second channel structure for forming the driving transistor corresponding to the switch transistor on the transistor region.

15. The pixel structure of claim 7, wherein the second dielectric layer further comprises a second dielectric via and partially exposes the second drain electrode for electrically connecting the pixel electrode to the second drain electrode by way of the second dielectric via.

16. A pixel structure, comprising:
a substrate, for defining a transistor region;
a switch transistor disposed on the transistor region of the substrate;
a first dielectric layer disposed on the substrate to cover the switch transistor;
a conducting connection line disposed on the first dielectric layer and over the transistor region;
a driving transistor disposed on the first dielectric layer for vertically stacking the driving transistor over the switching transistor and the transistor region, wherein the switch transistor connects the driving transistor by way of the conducting connection line;
a capacitor; and
a pixel electrode electrically connected to the driving transistor.
